(19) United States
(12) Patent Application Publication
(10) Pub. No.: US 2010/0327710 A1
(43) Pub. Date: Dec. 30, 2010

(54) Loop tag housing

(75) Inventors: Chester Kolton, Westfield, NJ (US); Michael Norman, East Brunswick, NJ (US); Robert Whittemore, Montgomery, NY (US)

Correspondence Address: HOFFMANN & BARON, LLP, 6900 JERICHO TURNPIKE, SYOSSET, NY, 11791, US

(73) Assignee: B&G International, Inc.

(21) Appl. No.: 11/888,619

(22) Filed: Aug. 1, 2007

Related U.S. Application Data
(60) Provisional application No. 60/901,073, filed on Feb. 13, 2007.
(60) Provisional application No. 60/835,014, filed on Aug. 2, 2006.

(51) Int. Cl. H05K 5/02

(52) U.S. Cl. 312/223.1

(57) ABSTRACT

An electronic tag housing assembly is attachable to an article. The tag housing assembly includes a tag housing and an elongate wire loop extending from the tag housing. The tag housing supports an electronic tag therein. The wire loop may be placed around the article and then attached to the tag housing in such a manner that it cannot be nondestructively removed therefrom. Such removal would provide evidence of tampering.

### CROSS-REFERENCE TO RELATED APPLICATION:

This application claims priority to U.S. Provisional Patent Application No. 60/901,073, filed on Feb. 13, 2007, and U.S. Provisional Patent Application No. 60/835,014, filed on Aug. 2, 2006, which are incorporated herein by reference.

### FIELD OF THE INVENTION

The present invention relates generally to an electronic tag housing used to support electronic tags. More particularly, the present invention relates to a loop tag housing which supports an electronic tag and which is securely attachable to an article by use of the loop.

### BACKGROUND OF THE INVENTION

It is widely known to use electronic tags for various purposes. Electronic article surveillance (EAS) tags as well as radio frequency identification (RFID) tags are used for purposes such as tracking sales and shipments of products to which they are attached. These tags may also be used to provide theft deterrence to articles to which they are attached.

Many articles which require the use of electronic tags may have portions thereof in a closed circumferential configuration. These article may include watches, bracelets, necklaces and the like. One technique for applying a tag to such an article is to provide a tag housing having a longitudinal strap extending therefrom. The strap could be extended through or “looped” about, for example, the necklace and then reattached to the plastic housing. Thus, the tag housing would hang from the necklace and could be used for other purposes such as advertising and price information.

In order to prevent the unauthorized removal of the tag housing from the article, it would be necessary to assure that the strap is securely attached to the housing once threaded or looped through the article so that it cannot be nondestructively removed.

It is, therefore, desirable to provide an electronic tag housing of this type which can easily manufactured and applied, yet remain securely attached.

### SUMMARY OF THE INVENTION

The present invention provides an electronic tag housing assembly which includes an elongate tag housing having opposed ends. The electronic tag is supported within the housing. The housing includes an elongate base having a hook at one end. An elongate cover overlies the base and supports the tag therebetween. An elongate slide is supported between the cover and the base for slidable movement with respect thereto. An elongate wire loop has portions thereof secured to the housing between the cover and the base and has a looped end for attachment to the hook of the base. The slide is movable from a first position permitting access to the hook for attachment of the looped end, to a second position preventing removal of the looped end.

It is contemplated that the slide in the base would employ a one-way detent structure to permit movement of the slide from the first position to the second position.

The wire may be formed of plastic coated metal to prevent unauthorized removal.

In a further embodiment of the present invention, an electronic tag housing assembly includes an elongate housing and an electronic tag supported in the housing. The housing includes a base and a cover affixed to the base supporting the tag therebetween. An elongate flexible wire is fixedly supported at one end between the cover and the base. The wire includes a loop at the other end. The housing and cover define a slot in the housing for receiving the wire loop. A movable lock is insertably received in the slot for movement between an open position wherein the loop is insertable into the slot and a closed position securing the loop in the slot.

### BRIEF DESCRIPTION OF THE DRAWINGS

FIGS. 1 and 3 are perspective showings of the loop tag housing assembly of the present invention.

FIG. 4 is an enlarged partial perspective view of the loop tag housing assembly of the present invention showing a base, a cover, a slide and a wire loop forming the looped tag housing assembly.

FIG. 5 is a partial perspective view of the assembly with the cover removed.

FIG. 6 is a partial perspective view of the assembly with the cover and slide removed.

FIG. 7 is a perspective showing of the base of the assembly of the present invention.

FIG. 8 is a perspective showing of the slide of the assembly of the present invention.

FIGS. 9 and 10 are top and bottom views respectively of the cover of the assembly of the present invention.

FIG. 11 is an exploded perspective view of a further embodiment of loop tag housing assembly of the present invention.

FIG. 12 is an assembled perspective view of the loop tag housing assembly of FIG. 7.

FIG. 13 is plan view of the loop tag housing assembly of FIG. 8.

FIG. 14 is an enlarged showing of a portion of the loop tag housing assembly of FIG. 9.

FIG. 15 is a sectional showing of the loop tag housing assembly of FIG. 12.

FIGS. 16-17 are perspective showings respectively of the cover and base of the loop tag housing assembly of the present invention.

### DETAILED DESCRIPTION OF THE PREFERRED EMBODIMENT

The present invention provides an electronic tag housing assembly which may be used to secure an electronic tag such as a radio frequency identification (RFID) tag or an electronic article surveillance (EAS) tag to an article.

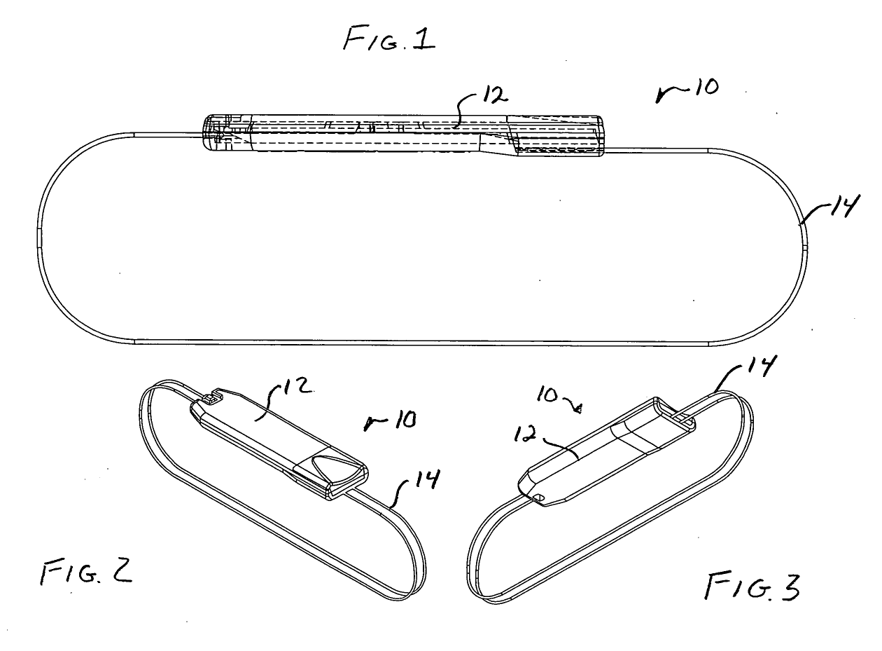

The housing assembly 10 of the present invention is shown in FIGS. 1-3. The housing assembly 10 includes an elongate tag housing 12 and a double wire loop 14 secured at opposite ends of the tag housing 12.

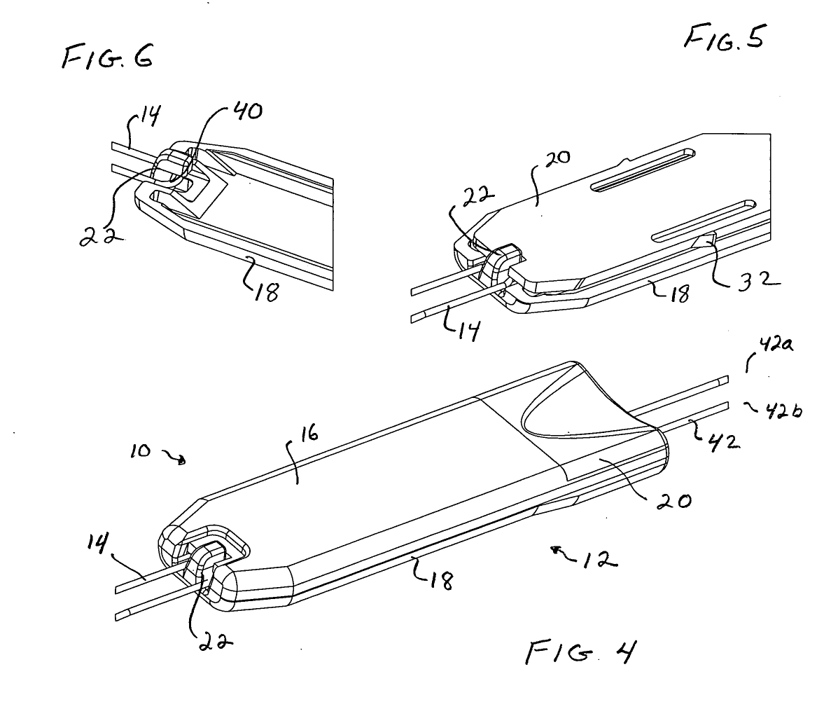

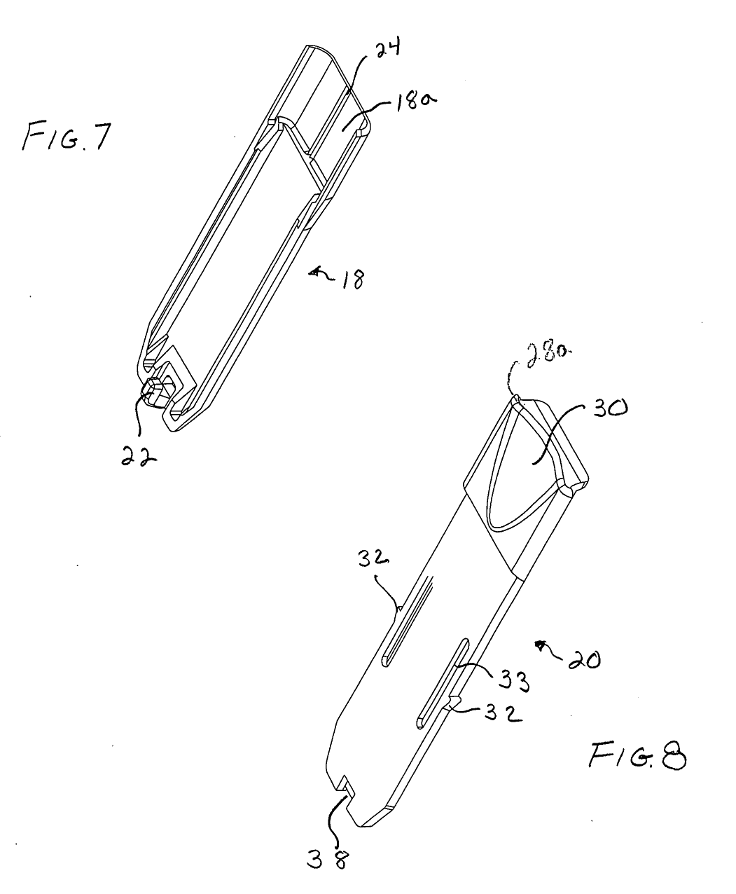

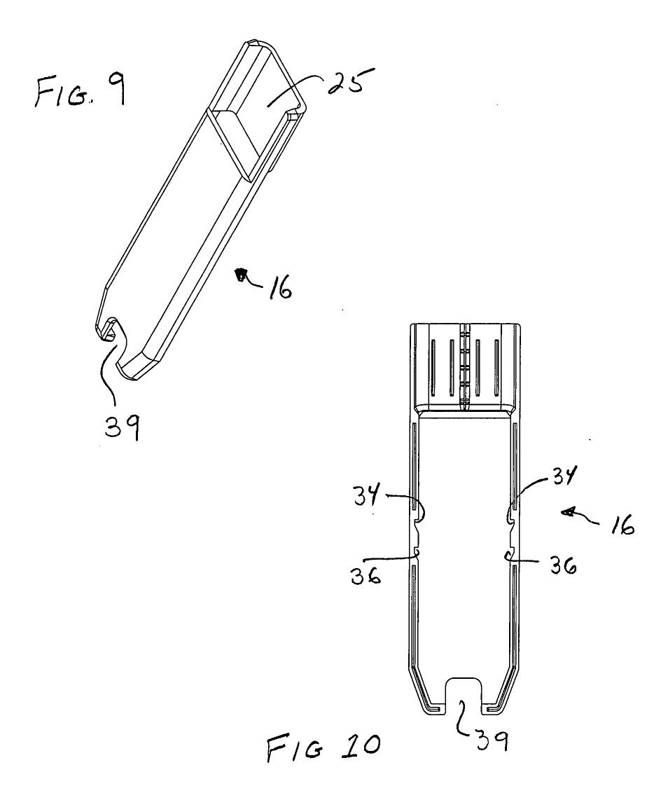

The housing is more fully shown FIGS. 4-6. The tag housing 12 includes a cover 16, a base 18, and slide 20 positioned therebetween. The slide 20 is designed for slidable movement between the base and the cover. One end of the base includes an upwardly extending hook 22. As will be described in further detail hereinbelow, the hook 22 is designed to provide a catch for double wire loop 14.

The base 18 which is more fully shown in FIG. 7 includes at the end opposite the hook 22, a pair of channels 24 for accommodating the ends of the double wire loop. The channels 24 are shown to be side-by-side, but other configurations are possible.

The slide 20, more fully shown in FIG. 8, is resident in the base 18 between the base and the cover 16. The cover 16 which is more fully shown in FIGS. 9 and 10 has a recessed portion 25 which generally overlies the end 18a of base 18 so that an end portion 28a of the slide 28 can extend outwardly thereof for manual engagement. In this regard the end 28a includes a thumb groove 30 to allow manual manipulation.

The slide 16 has a pair of outwardly extending detents 32 which are engageable with like recesses 34, 36 in the undersurface of the cover 16 so as to make the slide movable between a first position and a second position. In this first position, the detents 32 are supported in recesses 34, and in the second position, the detents 32 are supported in the recesses 36. This allows for a one-way locking of the slide 20. Slots 33 adjacent detents 32 allow for flexing so as to permit resilient movement of the detents 32. Also, the forward end of slide 20 includes a slot 38 which accommodates and surrounds hook 22 of base 18 as shown in FIGS. 4-6, when the slide is in the second position. The cover 16 has a similar slot 39 to accommodate hook 22. Other lock type mechanisms may also be employed.

As shown in FIGS. 4-6, double wire loop 14 is an elongate extent of wire which is plastic coated stainless steel which renders the wire difficult to sever and remove from the article about which it is placed. The wire is folded upon itself to form a looped end 40 and a non-joined end 42 have end extents 42a and 42b. The two side-by-side end extents of the wire, are placed in the channels 24 of the base and are covered by the extending portion of cover 16. Thereupon, the cover and base, with the slide positioned therebetween, can be ultrasonically welded together securing the end extent of the wire to the tag housing.

The tag housing assembly 10 is initially provided with the slide moved to rearward open position exposing the hook 22 of base 18. In this position, the outwardly extending detents 32 are within the recesses 34. The wire 14 may be looped through the article to which it is desired to be attached. Thereafter, the looped end 40 of the wire may be placed around the hook. The slide is then moved from its first position to its second position whereupon the slot 38 of the slide 16 surrounds the hook 22 preventing the wire loop 40 from being removed from the tag housing. This prevents the loop from being removed from the hook in a nondestructive manner. Any destructive removal would provide evidence of tampering.

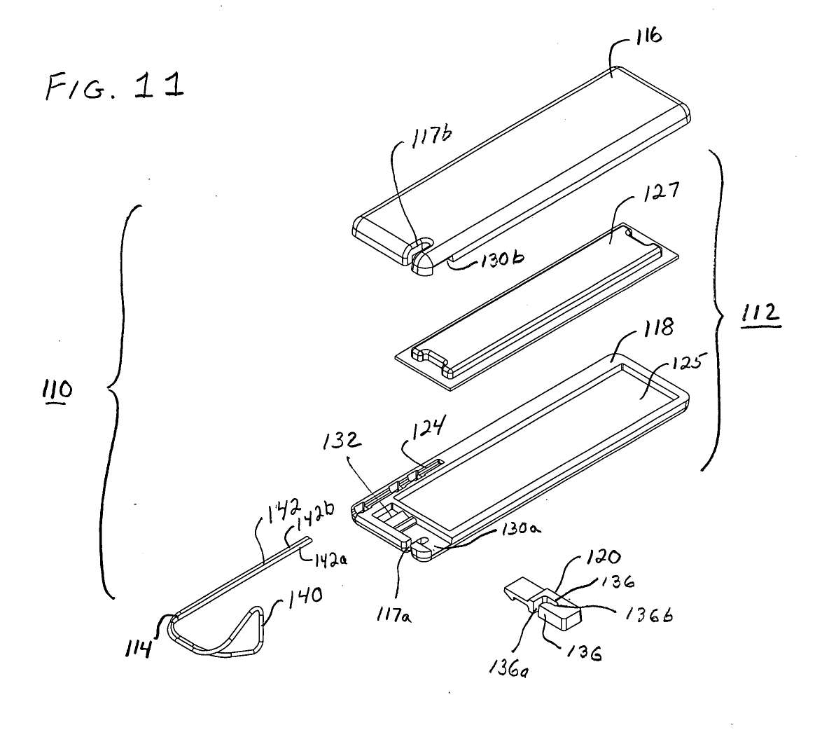

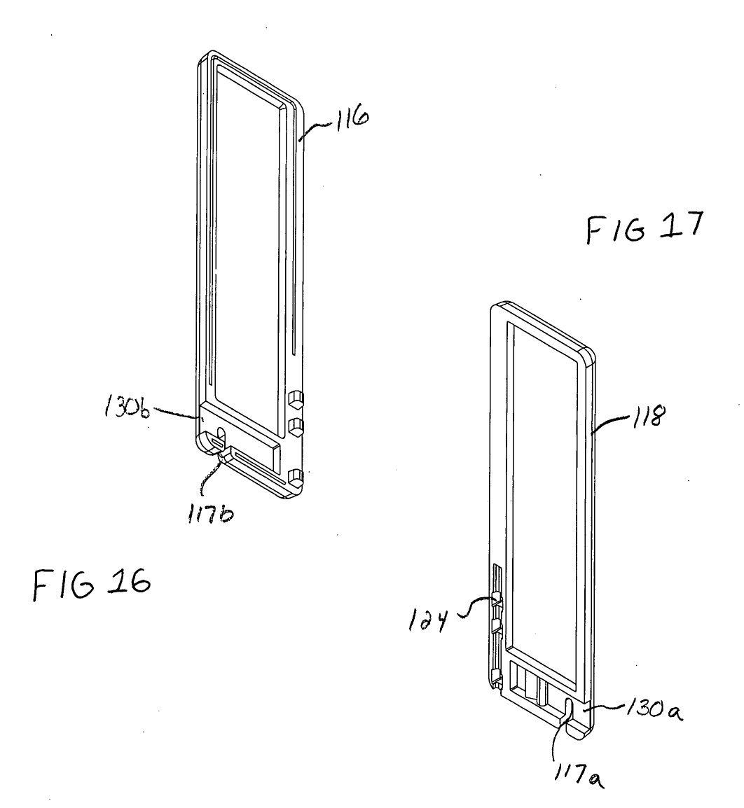

A further embodiment of the present invention is shown with respect to FIGS. 11-17.

As shown in FIG. 11, housing assembly 110 includes an elongate tag housing 112 and a wire 114 secured at one end of the tag housing 112. The elongate tag housing 112 is generally rectangular in shape. However, other shapes are within the contemplation of the present invention. Housing 112 includes a cover 116, a base 118 and a lock 120 slidably supported within the housing 112 as will be described in further detail hereinbelow. Base 118 and the cover 116 mutually define a cavity 125 which accommodates an electronic tag 127.

Wire 114 is an elongate extent of wire, which may be plastic coated stainless steel, which renders the wire difficult to sever and remove from the article on which it is placed. The wire may be flexible or it may be a stiff wire. The wire is generally folded upon itself to form a looped end 140 and a non-joined end 142 having end extents 142a and 142b. The two end extents are placed in side-by-side relationship. As also shown in FIG. 15, base 118 includes an elongate upwardly opening channel 124 which is in communication with the end of base 118. The side-by-side ends 142a and 142b are placed within the channel so that when the cover 116 is attached to the base 118 the side-by-side ends are secured therein.

It is also contemplated that the ends 142a and 142b of wire 114 may be further secured within the channel 124 by ultrasonic welding or other fastening means. For example, a permanent adhesive may be used to secure the ends within the channel 124. The ends 142a and 142b are permanently secured within the channel 124 between base 118 and cover 116.

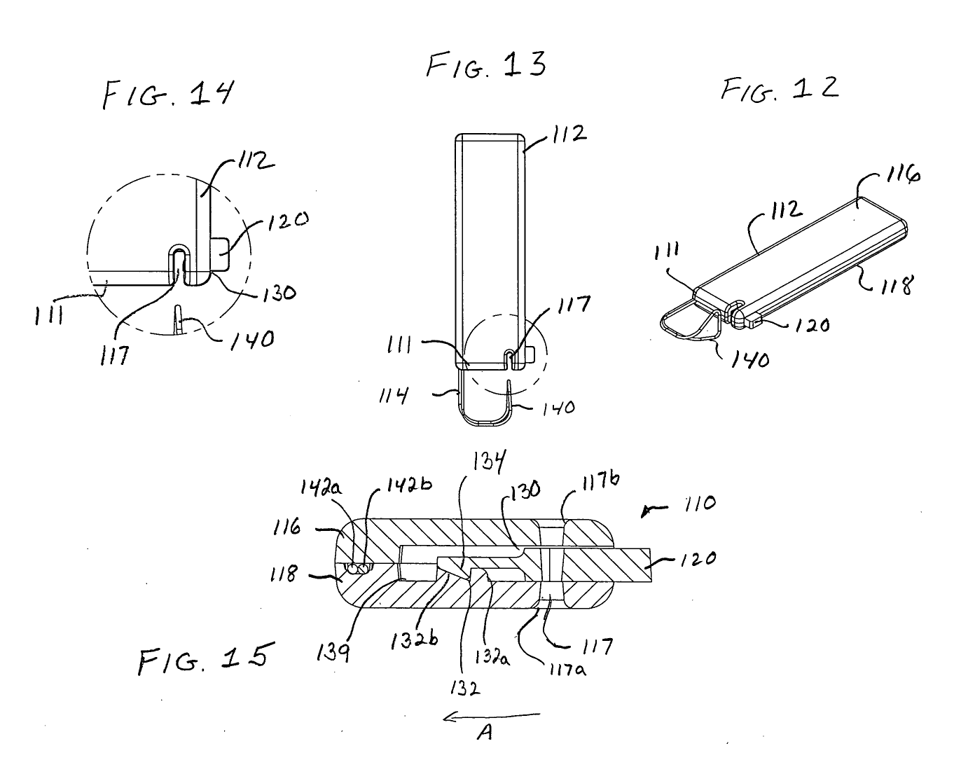

As particularly shown in FIGS. 12-15, the looped end 140 of wire 114 extends outwardly from one end 111 of the assembled housing 112. Both the base 118 and cover 116 define slot portions 117a and 117b respectively which, when assembled, form a longitudinal slot 117 continuously through one end 111 of housing 112. The slot 117 extends from end 111 of housing 112 adjacent channel 124.

As shown in more detail in FIG. 14, the looped end 140 of wire 114 is designed for insertion into slot 117. In typical use, the wire 114 extending from housing 112 would be wrapped around the article to which the housing is to be secured. Thereafter, the looped end 140 is inserted into slot 117.

In order to permanently secure the housing assembly 110 to the article, lock 120 is provided. Lock 120 is an elongate hook-shape member which is inserted into the housing 112 laterally through an elongate side passage 130 formed adjacent one end 111 of housing 112. As shown in FIGS. 11 and 15-17, side passage 130 is formed by aligned passage portions 130a in base 118 and 130b in cover 116. Side passage 130 is in transverse communication with slot 117. Formed in passage 130 is a detent structure 132 which works with cooperative detent structure 134 on lock 120 to allow movement of the lock 120 between first or open position shown in FIG. 15 permitting insertion of the loop end of the wire into slot 117 and a second or locked position which locks the looped end 140 of wire 114 within slot 117.

With additional reference to FIG. 15, detent structure 132 includes a curved ramp 132a and an upperwardly angled rib surface 132b. The detent structure 132 is cooperative with a hook-like detent structure 134 on lock 120. Lock 120 further includes an L-shaped channel 136 therethrough. L-shaped channel 136 includes a base portion 136a which opens laterally from lock 120 and is in alignment with slot 117 when lock 120 is positioned in its first position. This allows insertion of the looped end 140 of wire 114 into slot 117.

In this position, the hook-like detent structure 134 of lock 120 is positioned between curved rib 132a and angled rib surface 132b as shown in FIG. 15. This position prevents the lock from being removed from the housing 112. The lock 120 may be moved inwardly to its second or locked position. In this position, the tapered surface 134a of hook 134 rides over the angled rib surface 132a and the hook 134 is lockingly supported in a recess 139 within passage portion 130. During such movement, the looped end of wire 114 extends through the extending arm portion 136b of channel 136. A finger portion 136 of lock 120 blocks the slot 117 preventing withdrawal of the looped end 140 of wire 114. The arrangement of cooperating detent structure 132 of the side passage 130 and the detent structure 134 of lock 120 provides one way movement of the hook in the passage. Thus, once moved from the first position to the second position, the lock cannot be moved in reverse. This prevents removal of the looped end 140 of wire 114 from slot 117.

While the particular detent structure shown herein includes ramps and hooks, other detent structures which provide one way securement may also be employed. Lock 120 is therefore movable from a first position permitting entry of the looped 140 of wire 114 into slot 117 to a second position preventing withdrawal of the looped end therefrom. Once in the second or locked position, the wire cannot be nondestructively removed from the housing 112. Thus, when used as a security or identification device, the housing assembly 110 cannot be removed from an article without severing the flexible wire and thereby providing an indication of tampering.

Various changes to the foregoing described and shown structures would now be evident to those skilled in the art. Accordingly, the particularly disclosed scope of the invention is set forth in the following claims.

What is claimed is:

1. An electronic tag housing assembly comprising:
an elongate housing having opposed ends; and
an electronic tag supported with said housing;
said housing including:
an elongate base having a hook at one end;
an elongate cover overlying said base and supporting said tag therebetween;
an elongate slide slidably supported between said cover and said base; and
an elongate wire loop having portions thereof secured between said base and said cover at one end thereof and a looped end for attachment to said hook;
said slide being movable from a first position permitting access to said hook for said attachment of said looped end of said wire loop, to a second position preventing removal of said looped end therefrom.

2. An electronic tag housing assembly of claim 1 wherein said base and said cover define a cavity therebetween for support of said tag.

3. An electronic tag housing assembly of claim 1 wherein said wire loop comprises an elongate wire having opposed ends wherein said ends of said wire are brought together to form said loop.

4. An electronic tag housing assembly of claim 3 wherein said ends of said wire are secured between said base of said cover.

5. An electronic tag housing assembly of claim 4 wherein said wire is plastic coated metal and wherein said base and said cover are plastic and said ends of said wire are ultrasonically secured between said base and said cover.

6. An electronic tag housing assembly of claim 1 wherein said cover includes a recess at said one end thereof for exposing one end of said slide for manually sliding said slide between said first and said second positions.

7. An electronic tag housing assembly of claim 6 wherein said other end of said slide includes a slot for accommodating said hook of said base in said second position.

8. An electronic tag housing assembly of claim 1 wherein said slide and said base include cooperative detent structure for mounting said slide in said first and second position.

9. An electronic tag housing assembly of claim 1 wherein said cooperative detent structure permits one-way movement of said slide from said first position to said second position.

10. An electronic tag housing assembly of claim 9 wherein in said second position said slide is non-removably secured.

11. An electronic tag housing assembly comprising:
an elongate housing;
an electronic tag supported in said housing;
said housing including a base and a cover affixed to said housing supporting said tag therebetween;
an elongate flexible wire fixedly supported at one end between said cover and said base, said wire having a loop at said other end, said housing and cover defining a slot in said housing for receiving said wire loop; and
a movable lock insertably received in said slot for movement between an open position wherein said loop is insertable into said slot and a closed position securing said loop in said slot.

12. An electronic tag housing assembly of claim 11 wherein in said closed position said lock is non-removably secured to said housing.

13. An electronic tag housing assembly of claim 12 wherein said base includes a channel for receipt of said one end of said wire.

14. An electronic tag housing assembly of claim 13 wherein said one end of said wire is secured in said channel.

15. An electronic tag housing assembly of claim 14 wherein said wire is plastic coated metal and wherein said base and said cover are plastic and wherein said one end of said wire is ultrasonically welded in said channel between said base and said cover.

16. An electronic tag housing assembly of claim 12 wherein said base and said lock include cooperative detent structure to non-removably secure said lock in said second position.

17. An electronic tag housing assembly of claim 11 wherein said lock includes a portion thereof extending into said loop in said closed position.

18. An electronic tag housing assembly of claim 17 wherein said lock includes an L-shaped channel having a first portion thereof in alignment with said slot in said housing in said open position for insertable receipt of said loop.

19. An electronic tag housing assembly of claim 18 wherein said L-shaped channel has a second position for accommodating said loop in said closed position.
